(19) United States
(12) Patent Application Publication
(10) Pub. No.: US 2025/0291252 A1
(43) Pub. Date: Sep. 18, 2025

(54) STRUCTURE INCLUDING A PHOTORESIST UNDERLAYER AND METHOD OF FORMING SAME

(71) Applicant: ASM IP Holding B.V., Almere (NL)

(72) Inventors: Fanyong Ran, Tokyo (JP); João Ricardo Antunes Afonso, Tokyo (JP); Zecheng Liu, Tokyo (JP); Jerome Samuel Nicolas, Tokyo (JP)

(73) Assignee: ASM IP Holding B.V., Almere (NL)

(21) Appl. No.: 19/076,205

(22) Filed: Mar. 11, 2025

Related U.S. Application Data
(60) Provisional application No. 63/565,230, filed on Mar. 14, 2024.

(51) Int. Cl. G03F 7/11; G03F 7/004; G03F 7/075; G03F 7/16

(52) U.S. Cl. CPC G03F 7/11; G03F 7/0043; G03F 7/0752; G03F 7/167

(57) ABSTRACT

Methods of forming structures including a photoresist underlayer and structures including the photoresist underlayer are disclosed. Exemplary methods include forming the photoresist underlayer using a cyclical deposition process. Exemplary methods can additionally include forming a passivation layer and/or an adhesion layer.

### CROSS-REFERENCE TO RELATED APPLICATIONS

This application claims priority to U.S. Provisional Patent Application Ser. No. 63/565,230 filed Mar. 14, 2024 titled STRUCTURE INCLUDING A PHOTORESIST UNDERLAYER AND METHOD OF FORMING SAME, the disclosure of which is hereby incorporated by reference in its entirety.

### FIELD OF INVENTION

The present disclosure generally relates to structures that include a photoresist underlayer and to methods of forming such structures.

### BACKGROUND OF THE DISCLOSURE

During the manufacture of electronic devices, fine patterns of features can be formed on a surface of a substrate by patterning the surface of the substrate and etching material from the substrate surface using, for example, gas-phase etching processes. As a density of devices on a substrate increases, it becomes increasingly desirable to form features with smaller dimensions.

Photoresist is often used to pattern a surface of a substrate prior to etching. A pattern can be formed in the photoresist, by applying a layer of photoresist to a surface of the substrate, masking the surface of the photoresist, exposing the unmasked portions of the photoresist to radiation, such as ultraviolet light, and removing a portion (e.g., the unmasked or masked portion) of the photoresist, while leaving a portion of the photoresist on the substrate surface.

Recently, techniques have been developed to use extreme ultraviolet (EUV) wavelengths to develop patterns having relatively small pattern features (e.g., 10 nm or less). To form features on a substrate using EUV, a photoresist underlayer may be deposited onto a surface of a substrate, and then an EUV photoresist layer is deposited/coated overlying the photoresist underlayer. The photoresist underlayer can be used to promote adhesion between a surface of a substrate and the photoresist. Increased adhesion can mitigate photoresist pattern collapse, photoresist scum, and other photoresist defects that might otherwise occur.

Spin-on glass (SoG) is often used as an underlayer. The SoG underlayer generally has a thickness of about 10 nm or more. As such, SoG may be impracticable for some applications.

More recently, plasma deposited oxides have been investigated as possible materials for photoresist underlayers. However, such oxides generally exhibit a higher surface polarity than the (e.g., EUV) photoresist and may result in damage to underlying layers. Therefore, there is a desire for methods that mitigate damage to underlying material during formation or deposition of a photoresist underlayer.

Recently, metal oxide resists (MORs) have been developed for EUV applications. Compared to traditional chemically amplified resists (CARs), MORs are thought to exhibit better resolution for both line/space and pillar patterning and better local critical dimension (CD) uniformity (LCDU) on a pillar pattern. The better resolution can result in a reduced process complexity and cost of manufacturing devices. Further, use of refractory metal oxide barriers enable MORs to provide better pattern transfer for smaller features and thinner resists, and can enable better etch durability and selectivity.

An EUV dose during a photolithographic process is typically much higher than 193 nm immersion (193i) lithography ArF (argon fluoride) that can be used with more traditional photoresists. The EUV is generally higher, because a number of EUV photos is only about 1/14 of the photons provided using a 193i ArF lithographic process. The relatively low photo output can result in relatively large pattern roughness, which can result in stochastic defects in the photoresist pattern or devices formed using such EUV techniques. Moreover, high EUV dose results in relatively low throughput and thus is not well suited for high volume manufacturing. Therefore, there is a desire for techniques to use EUV and MORs with relatively high throughput.

Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

Various embodiments of the present disclosure relate to structures including photoresist underlayers and to methods of forming the photoresist underlayers and structures. While the ways in which various embodiments of the present disclosure address drawbacks of prior methods and structures are discussed in more detail below, in general, various embodiments of the disclosure provide a passivation layer that can protect an underlying layer (e.g., a carbon layer, such as a carbon hard mask layer) during a method to form a photoresist underlayer. Additionally or alternatively, exemplary methods can include forming a photoresist underlayer and a MOR overlying the photoresist underlayer.

In accordance with exemplary embodiments of the disclosure, a method of forming a structure comprising a photoresist underlayer includes providing a substrate within a reaction chamber; using a first cyclical process, passivating a surface of the carbon layer to form a passivated surface; and using a second cyclical process, forming a bulk photoresist underlayer overlying the passivated surface, wherein an oxidant is not provided to the reaction chamber during the first cyclical process. The substrate can include a carbon layer, such as spin on carbon (SoC), PECVD carbon, or the like, which may be suitable for use as a hardmask material. By not using an oxidant during the first cyclical process, damage to an underlying carbon layer that might otherwise occur can be mitigated. In accordance with examples of these embodiments, the first cyclical process includes providing an inert gas to the reaction chamber, pulsing a precursor to the reaction chamber, and pulsing a plasma power to the reaction chamber to form a plasma using the inert gas. The inert gas can be or include one or more of argon, helium, neon, krypton, xenon, ammonia, hydrazine, or hydrogen in any combination. In accordance with further examples, the method can include purging the reaction chamber after the step of pulsing the precursor and before pulsing the plasma power. In these cases, a plasma can be ignited after the step of purging the reaction chamber. In accordance with yet further examples, the precursor comprises a silicon precursor, such as a silicon precursor noted below. In accordance with still further examples, the second cyclical process includes providing a reactant to the reaction chamber, pulsing a precursor to the reaction chamber, and pulsing a plasma power to the reaction chamber to form a plasma using the reactant. In these cases, the reactant can be or include oxygen. In accordance with yet additional examples, the first cyclical process is repeated between about 10 cycles and about 500 cycles or between about 40 cycles and about 200 cycles. A (e.g., silicon) precursor used during the first cyclical process can be the same as a (e.g., silicon) precursor used during the second cyclical process.

In accordance with additional embodiments of the disclosure, a method of forming a structure including a photoresist underlayer includes using a cyclical process, forming a silicon oxycarbide underlayer overlying the substrate, and forming a metal oxide resist layer overlying the underlayer, wherein the silicon oxycarbide underlayer comprises about 50 to about 55 atomic percent oxygen. The silicon oxycarbide underlayer can additionally include about 10 to about 20 atomic percent carbon. In accordance with examples of these embodiments, the cyclical process includes providing a reactant to the reaction chamber, pulsing a precursor to the reaction chamber, and pulsing a plasma power to the reaction chamber to form a plasma using the reactant. In accordance with further examples, the reactant comprises a hydrogen-containing gas and/or an oxygen-containing gas. In accordance with further examples, the precursor comprises a silicon precursor that includes a central carbon atom bonded to two silicon atoms and/or a silicon precursor that includes a silicon atom bonded to two oxygen atoms. A chemical formula of the (e.g., silicon) precursor can consist of Si, C, H, and O. As set forth in more detail below, examples of the disclosure can include a step of densifying the silicon oxycarbide underlayer. Further examples can include passivating a surface of a substrate, such as by forming a passivation layer as described above.

In accordance with other embodiments of the disclosure, an adhesion layer can be formed between the photoresist underlayer and a photoresist layer, such as a MOR.

In accordance with yet further examples, the photoresist underlayer includes a bulk layer. The bulk layer can be densified.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a structure in accordance with exemplary embodiments of the disclosure.

FIG. 3 illustrates structures in accordance with exemplary embodiments of the disclosure.

FIG. 4 illustrates carbon loss versus a number of passivation layer cycles in accordance with exemplary embodiments of the disclosure.

FIG. 5 illustrates: a) thickness and carbon loss versus a number of bulk photoresist underlayer deposition cycles, b) thickness and carbon loss versus a number of bulk photoresist underlayer deposition cycles, and c) a number of incubation cycles versus a number of passivation layer cycles.

FIG. 6 illustrates: a) carbon loss versus a number of passivation layer cycles for porous carbon hardmask material and b) carbon loss versus a number of passivation layer cycles for dense carbon hardmask material in accordance with exemplary embodiments of the disclosure.

FIG. 7 illustrates another method in accordance with exemplary embodiments of the disclosure.

FIG. 8 illustrates a deposition process in accordance with exemplary embodiments of the disclosure.

FIGS. 9A and 9B illustrate defects versus critical dimensions for various process conditions.

FIGS. 10(a) illustrates dose versus oxygen concentration and (b) atomic percent carbon versus oxygen concentration in accordance with yet additional examples of the disclosure.

FIG. 11 illustrates an exemplary reactor system in accordance with additional examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood that the invention extends beyond the specifically disclosed embodiments and/or uses thereof and obvious modifications and equivalents thereof. Thus, it is intended that the scope of the invention disclosed should not be limited by the particular disclosed embodiments described below.

The present disclosure generally relates to methods of forming structures that include a photoresist underlayer and to structures including a photoresist underlayer. As described in more detail below, exemplary methods can be used to form structures with photoresist underlayers that provide desired properties, such as desired photoresist underlayer thickness (e.g., less than 10 or less than 5 nm), relatively low surface roughness, good adhesion to the photoresist, desired etch selectivity, desired thickness uniformity—both within a substrate (e.g., a wafer) and between substrates, high pattern quality (low number of defects and high pattern fidelity), low line width roughness (LWR), photoresist stability during EUV lithography processing—e.g., during any post-exposure bake (PEB), photoresist development, reworking of the substrate, reasonable EUV sensitivity, compatibility with integration (e.g., relatively low deposition temperatures), that mitigate damage to an underlying (e.g., carbon) layer, and/or that use a relatively low dose (e.g., less than a dose used for spin-on glass photoresist underlayers), particularly when used in connection with a metal oxide resist (MOR).

As used herein, the term “substrate” may refer to any underlying material or materials including and/or upon which one or more layers can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can additionally or alternatively include various features, such as recesses, lines, and the like formed within or on at least a portion of a layer of the substrate. In accordance with some examples, the substrate includes a surface or surface layer that includes a carbon material layer, such as spin on carbon (SoC), PECVD carbon, or the like.

In some embodiments, “film” refers to a layer extending in a direction perpendicular to a thickness direction. In some embodiments, “layer” refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

In this disclosure, “gas” may include material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution assembly, such as a showerhead, other gas distribution device, or the like, may be used for, e.g., sealing the reaction space, and may include a seal gas, such as a rare gas.

In some cases, such as in the context of deposition of material, the term “precursor” can refer to a compound that participates in the chemical reaction that produces another compound, and particularly to a compound that constitutes a film matrix or a main skeleton of a film, whereas the term “reactant” can refer to a compound, in some cases other than precursors, that activates a precursor, modifies a precursor, or catalyzes a reaction of a precursor; a reactant may provide an element (such as O, N, C) to a film matrix and become a part of the film matrix. In some cases, the terms precursor and reactant can be used interchangeably. The term “inert gas” refers to a gas that does not take part in a chemical reaction to an appreciable extent and/or a gas that excites a precursor when, for example, RF or microwave power is applied, but unlike a reactant, it may not become a part of a film matrix to an appreciable extent.

The term “cyclic deposition process” or “cyclical deposition process” may refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component.

The term “atomic layer deposition” may refer to a vapor deposition process in which deposition cycles, typically a plurality of consecutive deposition cycles, are conducted in a process chamber. The term atomic layer deposition, as used herein, is also meant to include processes with alternating pulses of precursor(s)/reactive gas(es), and purge (e.g., inert carrier) gas(es) and/or pulsing a power used to produce a plasma. Generally, for ALD processes, during each cycle, a precursor is introduced to a reaction chamber and is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas or an inert gas) may subsequently be introduced into the process chamber for use in converting the chemisorbed precursor to the desired material on the deposition surface. The reactant/inert gas can be capable of further reaction or interaction with the precursor. Purging steps can be utilized during one or more cycles, e.g., during each step of each cycle, to remove any excess precursor from the process chamber and/or remove any excess reactant and/or reaction byproducts from the reaction chamber.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. For example, the term “about” can refer to +/−20, 10, 5, 2, or 1 percent of a value. Further, in this disclosure, the terms “including,” “constituted by” and “having” can refer independently to “typically or broadly comprising,” “comprising,” “consisting essentially of,” or “consisting of” in some embodiments. In accordance with aspects of the disclosure, any defined meanings of terms do not necessarily exclude ordinary and customary meanings of the terms.

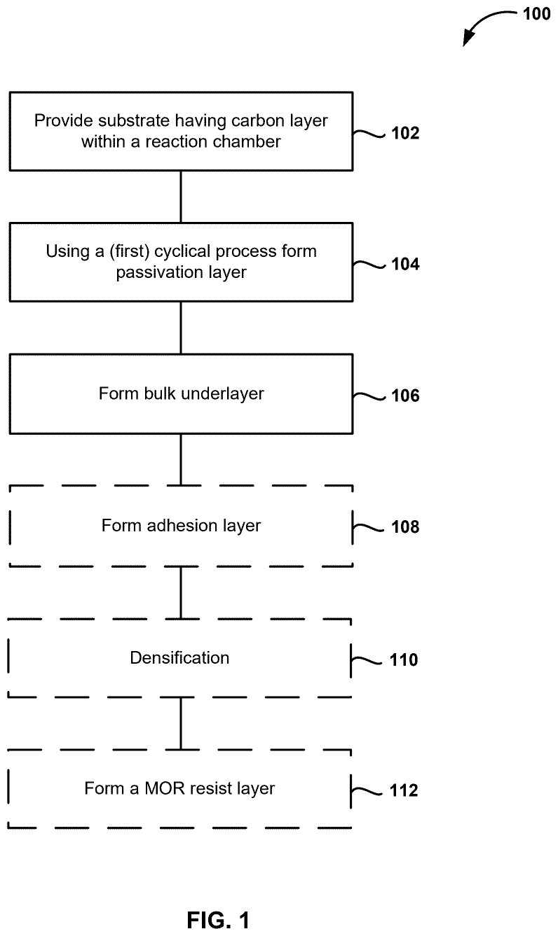

Turning now to the figures, FIG. 1 illustrates a method 100 of forming a structure comprising a photoresist underlayer in accordance with exemplary embodiments of the disclosure. Method 100 includes the steps of providing a substrate (step 102), using a first cyclical process, passivating a surface of the carbon layer to form a passivated surface (step 104), and using a second cyclical process, forming a bulk photoresist underlayer overlying the passivated surface (step 106). Method 100 can also include one or more of forming an adhesion layer (step 108), densifying a layer (step 110) and/or forming a metal oxide resist (MOR) layer (step 112).

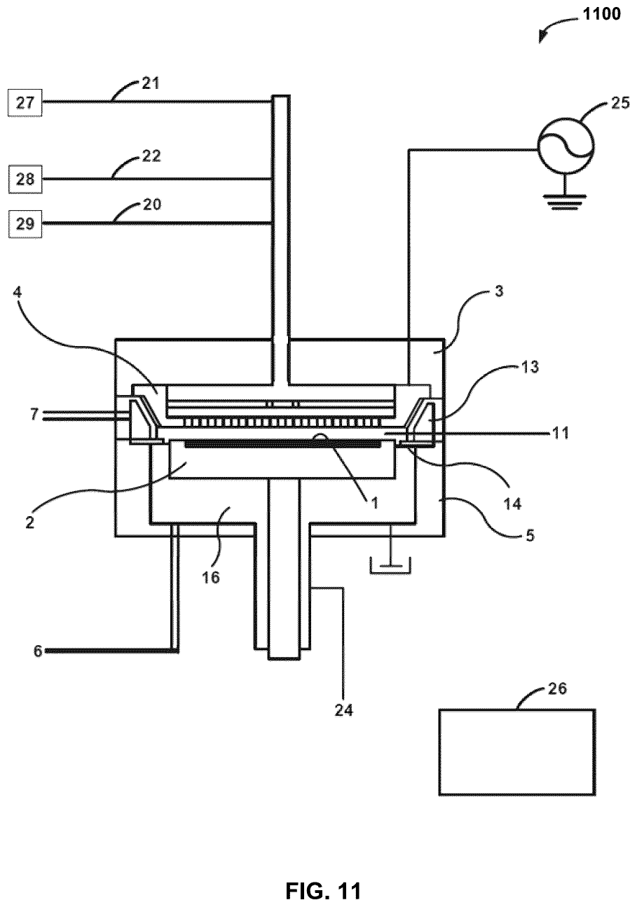

Step 102 includes providing a substrate, such as a substrate described herein, within a reaction chamber. In accordance with examples of these embodiments, the substrate includes a top layer or surface that includes carbon. By way of examples, the substrate can include a carbon material layer, such as spin on carbon (SoC), PECVD carbon, or the like. The substrate can include several layers underlying the carbon material layer. The reaction chamber can be as described below in connection with FIG. 11.

During step 104, a surface of the substrate is passivated using a first cyclical process to form a passivated surface. Step 104 can include forming a passivation layer. However, in some cases, a passivation layer may not be detected.

In general, the passivation layer is formed between the carbon layer and a bulk photoresist underlayer (sometimes referred to herein as underlayer). The process of passivating includes a less-aggressive, oxygen-free plasma process to mitigate damage that might otherwise occur to the carbon material layer. Thus, in accordance with examples, an oxidant is not provided to the reaction chamber during the first cyclical process.

The first cyclical process can include, for example, pulsing a precursor to the reaction chamber and/or pulsing a plasma power to the reaction chamber to form a plasma using the inert gas. By way of example, the first cyclical process includes providing an inert gas to the reaction chamber, pulsing a precursor to the reaction chamber, and pulsing a plasma power to the reaction chamber to form a plasma using the inert gas. In some cases, the inert gas can be a carrier gas that is provided with the precursor. In some cases, the inert gas can also be provided before and/or after a precursor and/or a reactant pulse to, e.g., purge the reaction chamber. For example, method 100 can include purging the reaction chamber after the step of pulsing the precursor and before pulsing the plasma power and/or after pulsing the plasma power. In accordance with examples, the inert gas can function as a reactant. The inert gas can be or include one or more of argon, helium, neon, krypton, xenon, ammonia, hydrazine, or hydrogen, in any combination. For example, the inert gas can be argon. In accordance with further examples, a plasma is ignited after the step of purging the reaction chamber after the precursor is pulsed to the reaction chamber.

A temperature within the reaction chamber during step 104 can be between about 50° C. and about 380° C. or between about 75° C. and about 190° C. A pressure within the reaction chamber during step 104 can be between about 200 Pa and about 1300 Pa or between about 330 Pa and about 1000 Pa. A plasma (e.g., Rf) power during a plasma pulse can be between about 20 W and about 1000 W or between about 35 W and about 500 W.

In accordance with further examples, the precursor comprises a silicon precursor. Exemplary silicon precursors suitable for step 104 include oxygen. A duration of the precursor pulse can be from about 0.1 s to about 5 s. A flowrate of the (e.g., silicon) precursor to the reaction chamber can be from about 10 sccm to about 6000 sccm.

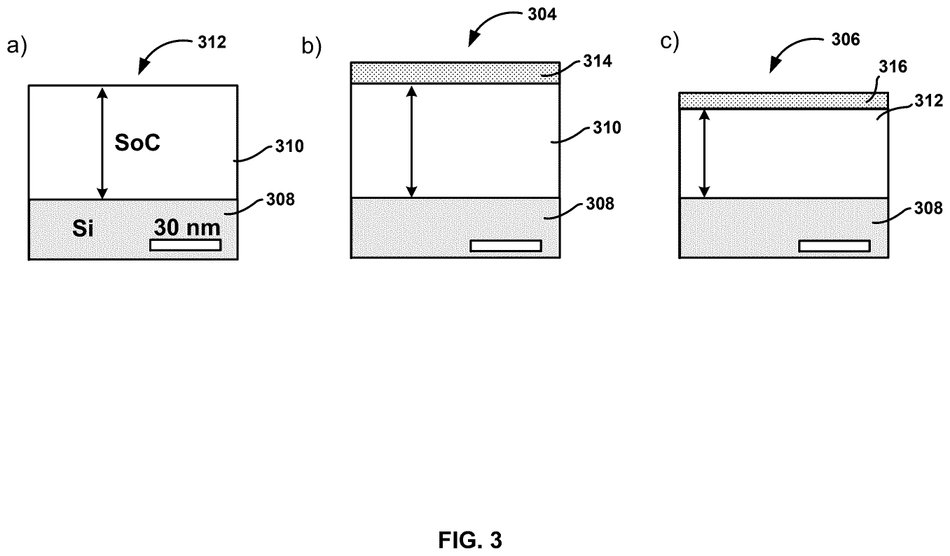

A number of cycles of the first cyclical process can be selected to mitigate carbon loss of the underlying carbon layer. FIG. 3 illustrates structures 302, 304, 306 that include a substrate 308 having a carbon material layer 310 thereon. FIG. 3a) illustrates structure 302 with the carbon material. FIG. 3b) illustrates structure 304 after forming a passivation layer 314 on structure 302. As illustrated, little to no carbon material layer 310 is removed during the formation of passivation layer 314. In contrast, as shown in FIG. 3c), if a bulk layer 316 is formed directly over carbon material layer, the carbon material layer 310 is reduced to carbon material layer 312.

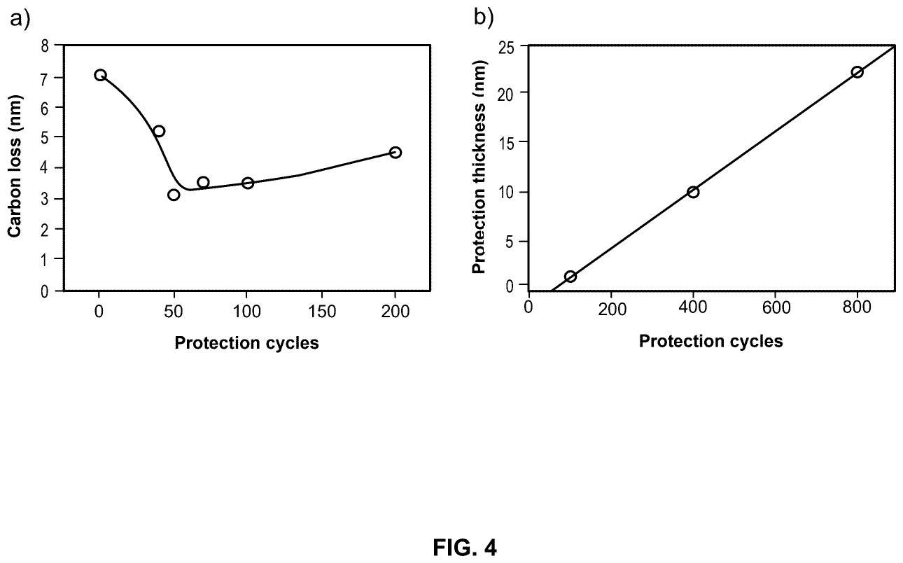

FIG. 4a) illustrates carbon loss measured during the deposition of several 5 nm bulk underlayer materials, with various numbers of passivation and bulk underlayer material cycles. Consequently, the number of bulk deposition cycles using O₂ plasma is decreased when the number of protection cycles increases. The carbon loss decreases steeply from 0 (no protection) to 60 cycles of protection deposition, whereas for additional cycles, the carbon loss tends to increase slightly. This distinct U-shaped curve reveals the existence of two (2) competing phenomena with opposite effects on the carbon loss.

In the first part of the curve of FIG. 4a), the protection layer efficiently manages to reduce the carbon loss. However, FIG. 4b) reveals that there is no actual protection deposition during the first 57 cycles due to a significant incubation period during the deposition on SoC. This suggests that there must be a passivation/hardening of SoC induced by the protection layer process—i.e., a passivation of the surface.

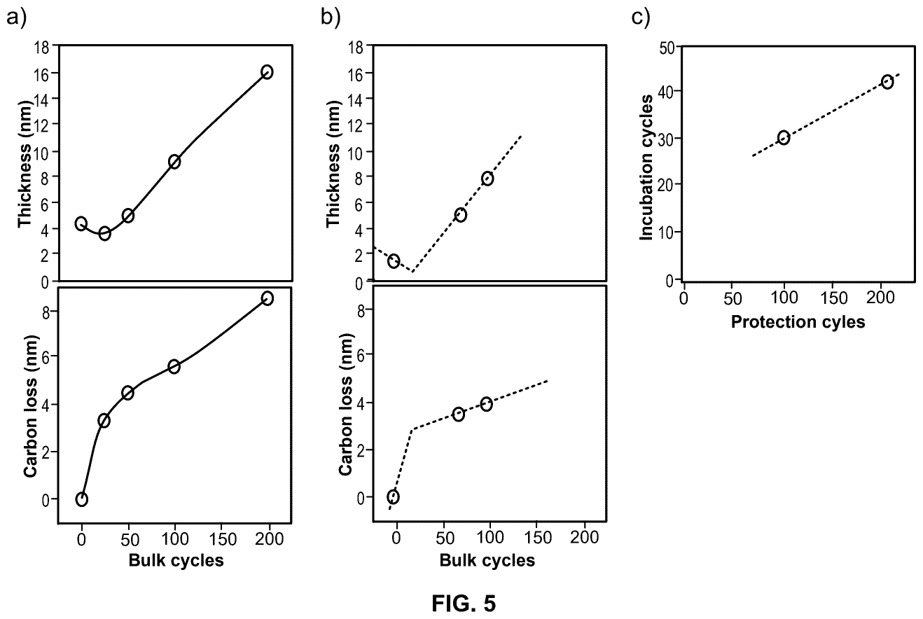

FIG. 5a) reveals a reduction of the underlayer thickness together with a rapid carbon loss in the first 25 cycles of the bulk layer deposition. This may be due to the etching of the carbon-rich protection layer by an O₂ plasma used during the bulk deposition. When the number of bulk deposition cycles is higher than about 50-75, the carbon loss is systematically lower when using a thinner 100 cycles protection layer as shown in FIG. 5b). This might be related to the etching and regrowth observed in the first 50 cycles of bulk deposition. The increase of this sort of incubation period with the number of protection deposition cycles is shown in FIG. 5c). The longer incubation would result from the longer etch time of thick protection layers and could lead to a higher carbon loss.

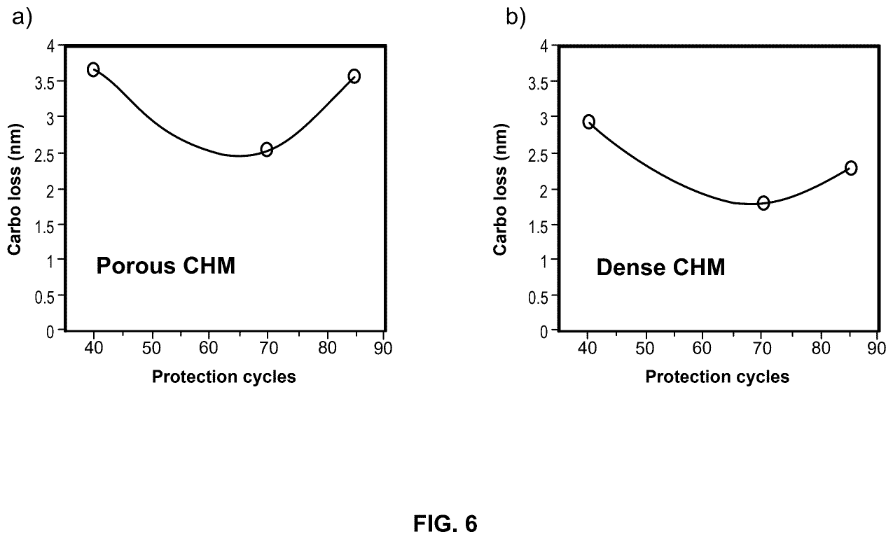

Carbon loss of different carbon-rich substrates: porous and dense PECVD-grown CHM are illustrated in FIG. 6. In this case, the bulk cycles were fixed at 74 and the protection deposition cycles were varied while the total thickness is kept in the 5-6 nm range. The porous CHM (FIG. 6a)) shows lower carbon loss than the dense CHM (FIG. 6b)). Both substrates show a similar U-shaped curve with a carbon loss minimum reached at ^{˜}60-70 cycles of protection deposition. In the case of the porous CHM in particular, the carbon loss increases very rapidly above 70 cycles of protection. Therefore, it is desirable to know with precision the position of the carbon loss minimum. In accordance with examples of the disclosure, the first cyclical process is performed between about 50 cycles and about 80 cycles or between about 60 cycles and about 70 cycles.

Turning again to FIG. 1, during step 106, using the second cyclical process, a bulk photoresist underlayer is formed on a surface of the substrate. The cyclical deposition process can include use of activated species (e.g., formed from one or more of precursor(s), reactant(s), and/or inert gas(es)) that are formed using one or more of a direct plasma and a remote plasma. Alternatively, step 106 can include a thermal cyclical deposition process. Use of cyclical deposition processes may be desirable, because they allow for the formation of a photoresist underlayer with desired thickness—e.g., less than 10 nm or less than or about equal to 5 nm, with improved thickness uniformity—both within a substrate and from substrate-to-substrate. Using a plasma-enhanced process may be desirable, because plasma-enhanced processes allow for deposition of the photoresist underlayer material at relatively low temperatures and/or relatively high rates—compared to thermal processes.

In accordance with exemplary embodiments of the disclosure, step 106 includes forming or depositing one or more of a silicon or metal oxide, a silicon or metal nitride, and a silicon or metal oxynitride. Such oxides, nitrides, and/or oxynitrides can also include carbon.

The photoresist underlayer can include, for example, one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride. The metal can include, for example, one or more metals selected from the group consisting of titanium, tantalum, tungsten, tin, and hafnium. In some cases, the photoresist underlayer includes carbon. The carbon can be incorporated into the photoresist underlayer as the photoresist underlayer is deposited and/or a carbon treatment can be applied to a surface of the photoresist underlayer. Additionally or alternatively, a carbon-containing layer or other layer can be deposited onto a surface of the photoresist underlayer. A thickness of the photoresist underlayer can be less than 10 nm, less than 5 nm, or greater than 3 nm and less than 10 nm.

A cyclical process for forming the photoresist underlayer suitable for step 106 includes providing a reactant to the reaction chamber (e.g., continuously through one or more cycles), pulsing a precursor to the reaction chamber, and pulsing a plasma power to the reaction chamber to form a plasma using the reactant. A number of cycles of step 106 can be between about 10 and about 50 or between about 100 and about 200 times before method 100 proceeds.

In some cases, the cyclical process for forming the photoresist underlayer can include (A) pulsing a first precursor comprising a metal into a reaction chamber, (B) pulsing a second precursor or reactant comprising an oxidant and/or nitriding agent into the reaction chamber, and (C) pulsing a carbon precursor into the reaction chamber. Each of the pulses can be separated by a purge step (e.g., by providing an inert gas to the reaction chamber). Further, each pulsing step or a combination of pulsing steps can be repeated a number of times prior to proceeding to the next step to tune a composition of the photoresist underlayer.

In accordance with exemplary aspects of the disclosure, a first precursor comprising silicon is provided. In some cases, the silicon precursor can also include carbon. Exemplary silicon precursors suitable for use in forming a photoresist underlayer are set forth below.

In accordance with other exemplary aspects of the disclosure, the first precursor comprises a metal. In these cases, the first precursor can include a transition metal, such as one or more metals selected from the group consisting of titanium, tantalum, tungsten, tin, and hafnium. The first precursor comprising a metal can also include carbon—e.g., one or more organic groups bonded directly or indirectly to a metal atom. By way of particular examples, the first precursor comprising a metal can include a metal halide or a metal organic compound, or an organometallic compound, such as one or more of tetrakis(dimethylamino)titanium (TDMAT), titanium isopropoxide (TTIP), titanium chloride (TiCl), tetrakis(ethylmethylamino)hafnium (TEMAHf), hafnium chloride (HfCl), trimethylaluminum (TMA), triethylaluminium (TEA), other metal halide, or other metal-containing compounds.

The reactant can include an oxidizing reactant, a nitriding reactant, or a reducing agent, such as a hydrogen-containing reactant. The oxidizing and/or nitriding reactant include reactants that include one or more of oxygen and nitrogen. In some cases, the reactant can include both nitrogen and oxygen. And, in some cases, the two or more oxidizing and/or nitriding reactant can be included in a single pulse. Exemplary oxidizing and nitriding agents include oxygen (O₂), water (H₂O), ozone (O₃), hydrogen peroxide (H₂O₂), CO₂, nitrous oxide (N₂O); exemplary hydrogen-containing reactants include hydrogen (H₂), and the like. As noted above, the oxidizing and/or nitriding reactant can be exposed to a (e.g., direct) plasma to form excited species for use in a PEALD process.

When used, the carbon precursor can include any suitable organic compound, such as compounds comprising carbon and oxygen. In some cases, the carbon precursor can also include nitrogen. The carbon precursor can be selected to react with, for example, an —OH terminated surface of metal oxides and/or a —NH₂ terminated surface of a metal nitride. Examples of suitable carbon precursors include one or more of organic compounds, such as acid anhydrate (e.g., an acetic anhydrate), toluene, diethylene glycol, triethylene glycol, acetaldehyde, and organosilicon compounds, such as silanes, and siloxanes. Exemplary organosilicon compounds include (n,n-dimethylamino)trimethylsilane, trimethoxy(octadecyl)silane, hexamethyldisilazane, trimethoxy(3,3,3-trifluoropropyl)silane, trimethoxyphenylsilane, trichloro(3,3,3-trifluoropropyl)silane and hexamethyldisilazane.

A temperature within the reaction chamber during step 106 can be between about 50° C. and about 380° C. or between about 75° C. and about 190 C. A pressure within the reaction chamber during step 106 can be between about 200 Pa and about 1300 Pa or between about 300 and about 800 Pa. A plasma (e.g., Rf) power during a plasma pulse can be between about 20 W and about 1000 W or between about 35 W and about 200 W. The plasma power can be higher or lower than the plasma power in step 104.

Once the bulk photoresist underlayer is formed during step 106, an adhesion layer can be formed during step 108. Step 108 can be performed in situ—within the same reaction chamber and without an air and/or a vacuum break.

Step 108 can include the substeps of providing a silicon precursor, providing an inert gas, and forming (e.g., pulsing plasma power) a plasma. Step 108 can include a cyclical deposition process, such as a PEALD process. For example, step 108 can include pulsing a silicon precursor to a reaction chamber, allowing the silicon precursor to react with a surface of a substrate, purging any unreacted precursor and/or byproducts, providing an inert gas to the reaction chamber (e.g., continuously during one or more cycles), and forming a plasma using the inert gas to form activated species that react with the silicon precursor or a derivative thereof to form the adhesion layer, and purging any excess reactive species and/or byproducts from the reaction chamber. Step 108 can be performed a number of times—e.g., between about 10 and about 100 or about 100 or about 200 or about 200 and about 500 times. The temperature and pressure during step 106 can be the same or similar for step 102 and/or 104. A thickness of the adhesion layer is greater than 0 and less than 2 nm.

In accordance with examples of the disclosure, the silicon precursor provided during step 108 does not comprise nitrogen. N-free precursors can be beneficial for use in forming an adhesion layer, because nitrogen is thought to exhibit a poisoning effect due to the presence of N atoms. In accordance with further examples, the silicon precursor consists of or consists essentially of Si, C, H, and O, which may be provided to the reaction chamber with the aid of a carrier gas. By way of examples, the silicon precursor can be selected from one or more of the group consisting of:

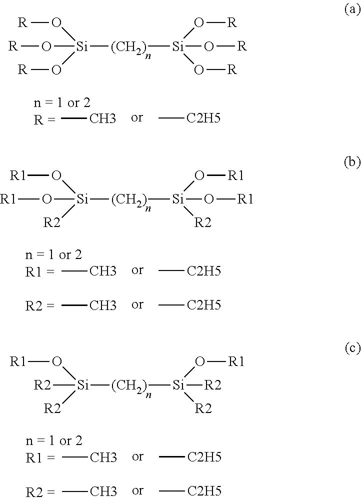

In accordance with further examples, the silicon precursor is selected from one or more of the group consisting of: 3-methoxypropyltrimethoxysilane, bis(trimethoxysilyl)methane, 1,2 bis(methyldimethoxysilyl)ethane, 1,2-bis(triethoxysilyl)ethane, 1,2-bis(triethoxysilyl)ethene, 1,2-bis(diethoxymethylsilyl)ethane, 1,2-bis(trimethoxysilyl)ethane, 1,1,3,3-tetramethoxy-1,3-disilacyclobutane, 1,1,3,3-tetraethoxy-1,3-disilacyclobutane, 1,1,3,3,5,5-hexamethoxy-1,3,5-trisilacyclohexane, 1,1,3,3,5,5-hexaethoxy-1,3,5-trisilacyclohexane. By way of particular example, the silicon precursor can be or include 3-methoxypropyltrimethoxysilane. A flowrate of the silicon precursor during step 108 can be between about 10 sccm and about 6000 sccm. A duration of the silicon precursor pulse can be between about 0.1 s and about 5 s.

A power to form the plasma can be about 30 W to about 1000 W. A frequency of the power to form the plasma can be between about 200 kHz and about 2.45 GHz. A flowrate of the inert gas can be between about 2 slm and about 10 slm. A duration of the plasma pulse can be between about 0.1 s and about 10 s.

During step 110, the bulk adhesion layer formed during step 108 can be densified. Although illustrated as a separate step, densification can be achieved by changing the deposition parameters of the bulk underlayer in order to get a denser bulk layer, using higher temperatures (e.g., temperatures between about 100° C. and about 500° C. or between about 150° C. and about 380° C.) to deposit the bulk underlayer (e.g., at the higher temperature ranges), thermal annealing processes (above 100° C. and below 1000° C.) under inert or oxygen atmosphere, or performing a UV Cure to densify the photoresist underlay.

Densification of the bulk layer (and optionally the adhesion layer) is thought to result in a higher generation of secondary electrons during photoresist exposure, due to the higher presence of oxygen atoms per unit. The dose reduces with increase in O %, which might be due to that O can generate more secondary electrons than Si and C. Secondary electrons can accelerate the reaction in resist exposure, therefore needing less photons for target CD, while not increasing any contaminants.

As illustrated, method 100 can also include a step 112 of forming a photoresist layer overlying and in contact with the adhesion layer and/or the densified layer. The photoresist can be a MOR that can be deposited using, for example, spin coating or a gas-phase process. A thickness of the MOR can be between about 10 and about 50 nm or between about 20 and about 40 nm.

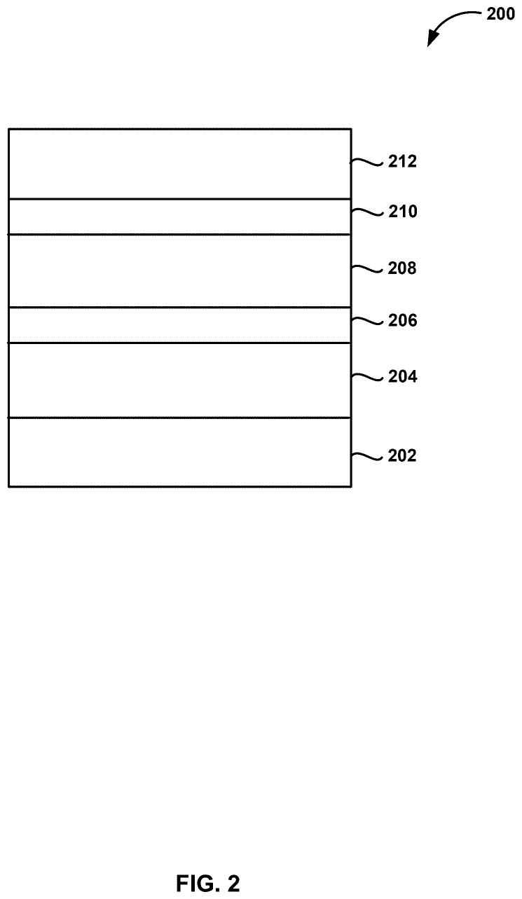

FIG. 2 illustrates a structure 200 in accordance with exemplary embodiments of the disclosure. Structure 200 can be formed using, for example, method 100.

As illustrated, structure 200 includes a substrate 202, a carbon material layer 204, a passivation layer 206, a bulk photoresist underlayer 208, a photoresist layer 212, and an adhesion layer 210 interposed between and in contact with photoresist underlayer 208 and photoresist layer 212.

Substrate 202 can include a substrate as described above. Carbon material layer 204 can be or include any carbon material as described herein. Carbon material layer 204 can be or include hardmask material. For example, carbon material layer 204 can include amorphous carbon or add-on films (e.g., a self-assembled monolayer (e.g., hexamethyldisilazane (HMDS)).

Passivation layer 206 can be formed according to step 104 described above. In accordance with examples of the disclosure, passivation layer 206 includes silicon and carbon.

Photoresist underlayer 208 can include a photoresist underlayer formed in accordance with a method described herein and/or have properties and/or material as described herein. Exemplary photoresist underlayers include one or more of a silicon or metal oxide, a silicon or metal nitride, and a silicon or metal oxynitride—any of which can include or not include carbon. For example, photoresist underlayer 208 can include one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride.

A thickness of photoresist underlayer 208 can depend on a composition of material layer 204, a thickness of material layer 204, a type of photoresist, and the like. In accordance with examples of the disclosure, photoresist underlayer 208 has a thickness of less than 10 nm or less than or about 5 nm or between about 3 nm and about 10 nm. If photoresist underlayer 208 is too thick, residual underlayer material may remain after an etch step. If photoresist underlayer 208 is too thin, photoresist underlayer 208 may not provide desired pattern transfer during an etch process.

Adhesion layer 210 desirably exhibits good adhesion and other properties as described herein. In accordance with examples of the disclosure, adhesion layer 210 includes silicon and can optionally include one or more of carbon, hydrogen, and oxygen. As noted above, adhesion layer 210 may desirably not include nitrogen.

Photoresist layer 212 can be or include a MOR. By way of particular example, photoresist layer 212 can be Sn-included MOR.

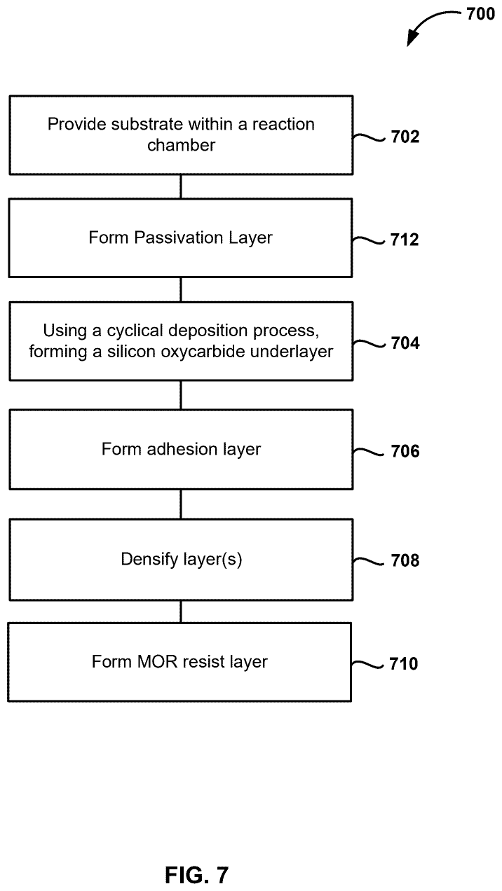

Turning now to FIG. 7, another method 700 of forming a structure comprising a photoresist underlayer in accordance with examples of the disclosure is illustrated. Method 700 includes providing a substrate within a reaction chamber (step 702) using a cyclical process, forming a silicon oxycarbide underlayer overlying the substrate (step 704), and forming a metal oxide resist layer overlying the underlayer (step 710). In accordance with examples of the disclosure, the silicon oxycarbide underlayer comprises about 50 to about 55 atomic percent oxygen. As illustrated, method 700 can also include one or more of forming an adhesion layer (step 706), densifying layers (step 708), and/or forming a passivation layer (step 712).

Step 702 can be the same or similar to step 102 described above. When the substrate includes a carbon layer or surface, method 700 can include step 712, which can be the same or similar to step 104 described above.

During step 704, a silicon oxycarbide (SiOC) underlayer is formed. As set forth in more detail below, a PEALD SiOC photoresist underlayer formed in accordance with step 704 showed lower dose requirements than spin-on glass (SoG, the current standard underlayer used in HVM) with the comparable lithography performance. In the exemplary embodiments, the SiOC photoresist underlayer only contains Si, O and C. Accordingly, use of such an underlayer does not give rise to concerns of metal doping and dry resist.

A temperature within the reaction chamber during step 704 can be between about 50° C. and about 380° C. or between about 75° C. and about 190° C. A pressure within the reaction chamber during step 704 can be between about 200 Pa and about 1300 Pa or between about 300 Pa and about 1000 Pa. A plasma (e.g., Rf) power during a plasma pulse can be between about 30 W and about 1000 W or between about 50 W and about 500 W. The plasma power can be higher or lower than the plasma power in step 712. A duration of a plasma power step (e.g., step 806) can be between about 0.1 s and about 5 s.

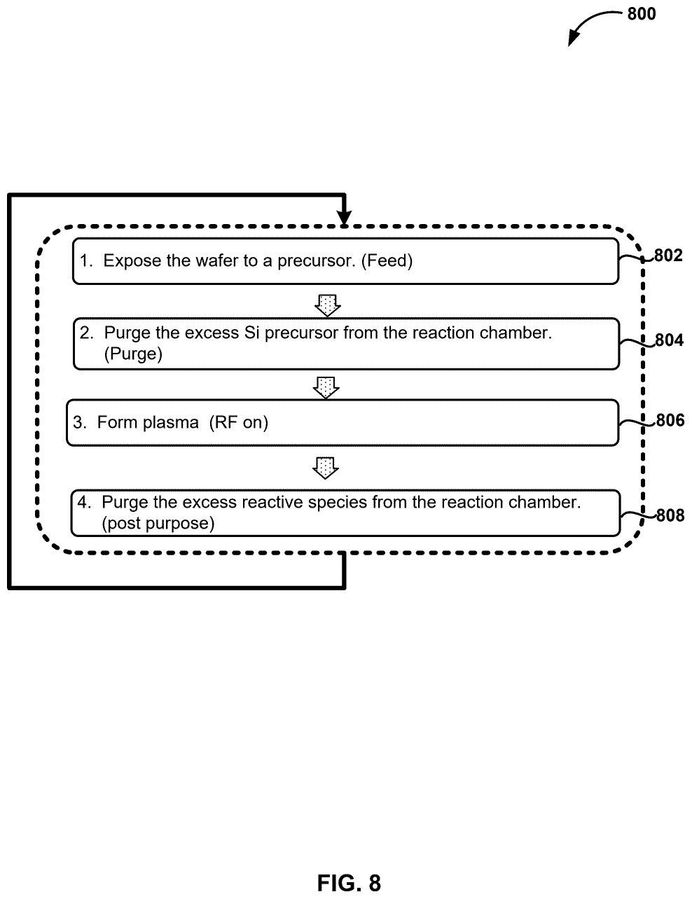

An exemplary cyclical process 800 suitable for step 704 is illustrated in FIG. 8. Cyclical process 800 includes providing a silicon precursor to the reaction chamber for a silicon precursor pulse (step 802), purging the reaction chamber (step 804), forming a plasma (step 806), and purging reactive species (step 808).

During step 802, a silicon precursor is provided to the reaction chamber for a pulse period. In accordance with examples of the disclosure, a chemical formula of the precursor consists of Si, C, H, and O. Suitable silicon precursors for step 802 include, for example, a silicon precursor selected from one or more of

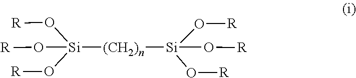

where n is 1 or 2 and each R is independently selected from a C1-C2 alky group;

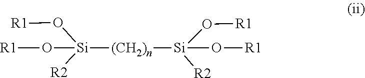

where n is 1 or 2 and each R1 and R2 is independently selected from a C1-C2 alky group or an alkene functional group;

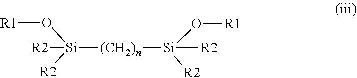

where n is 1 or 2 and each R1 and R2 is independently selected from a C1-C2 alky group or an alkene functional group; or

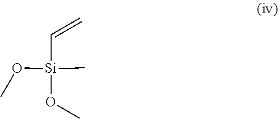

A duration of the pulse period can be from about 0.1 s to about 5 s or between about 0.15 and about 2 s.

A reactant can be or include an inert gas, and/or an oxidant, and/or a reducing gas. The reactant can be continuously flowed to the reaction chamber during one or more cycles of step 704. In some cases, the reactant can be or include one or more of a hydrogen-containing gas (e.g., H₂, NH₃, or the like), an oxygen-containing gas (e.g., N₂O, CO₂, or the like), and/or an inert gas.

Process 800 can be repeated a number of times. For example, process 800 can be performed between about 10 and about 1000 cycles or between about 50 and about 400 cycles.

To achieve desired performance of the underlayer, the photoresist underlayer can desirably include about 50 to about 55 atomic percent oxygen and/or about 10 to about 20 atomic percent carbon.

Returning again to FIG. 7, method 700 can include an adhesion layer formation step (step 706) a densification step (step 708) and/or a MOR resist formation step (step 710). Step 706 can be the same or similar to step 108. Step 708 can be the same or similar to step 110. Step 710 can be the same or similar to step 112.

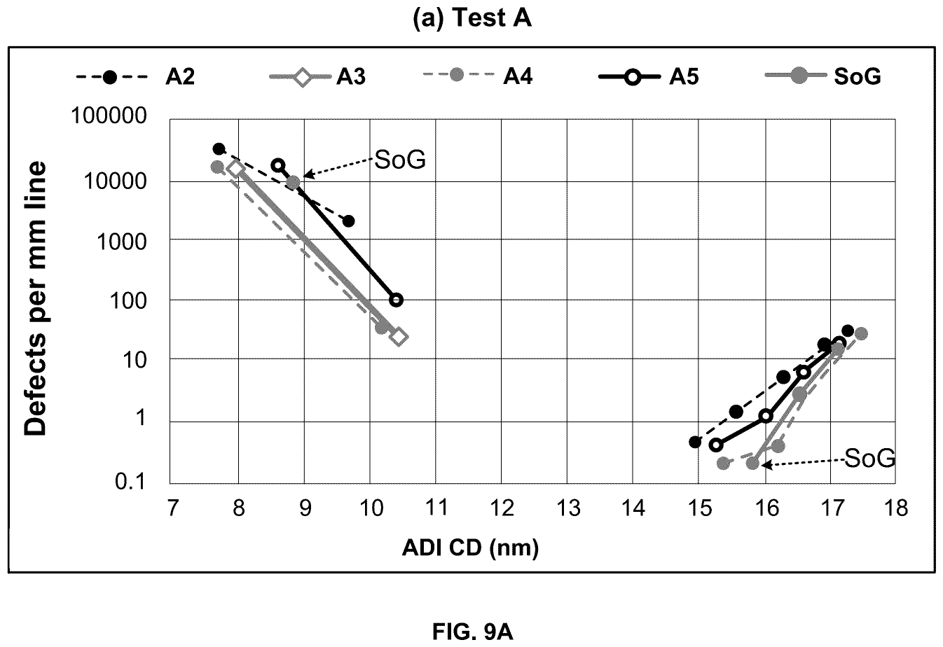

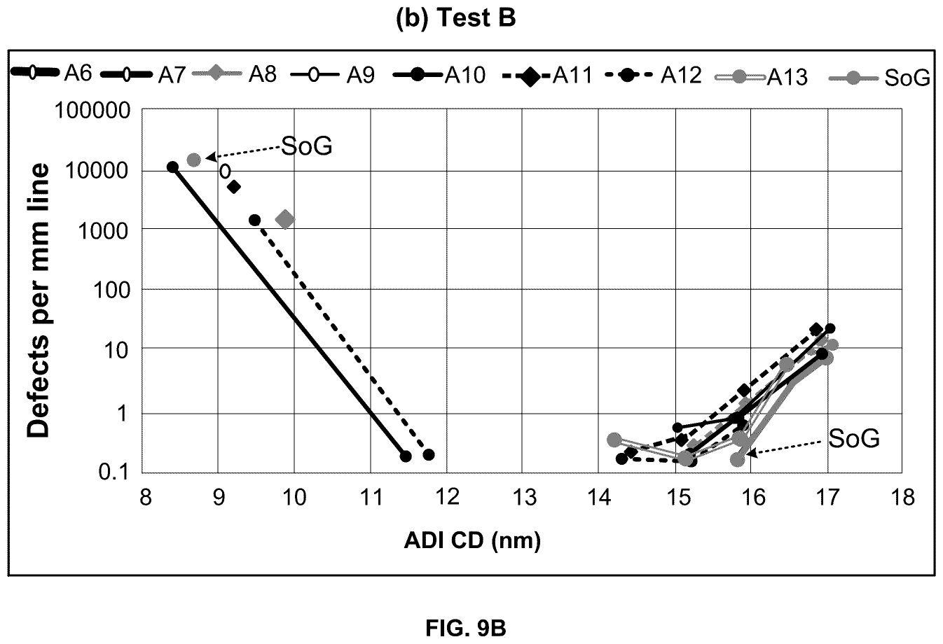

To illustrate the advantages of forming the underlayer (e.g., the bulk underlayer) with a desired oxygen and/or carbon content, Table 1 shows the after-development inspection (ADI) dose and line width roughness (LWR)/line edge roughness (LER) data of PEALD photoresist underlayers deposited at different conditions, SoG data is also listed as a comparison. The EVU lithography test is done using MOR resist. The underlayers deposited by Ar plasma showed high dose and worse LWR/LER. Some underlayers, such as those labeled A3, A4, A5, A8, A11 (Table 1 and FIGS. 9A and 9B), with lower dose and comparable LWR/LER than SoG, are obtained by H and O plasma deposition. The obtained lowest dose is 60.5 mJ/cm², ^{˜5.5}% dose reduction achieved. Accordingly, in accordance with examples of the disclosure, a hydrogen-containing gas and/or an oxygen-containing gas are provided as a reactant during step 704. By way of particular example, the reactant can be or include Ar, He, N₂, O₂, CO, CO₂, N₂O, CxHy, where x is between 1 and 8 and y is between 2and 18, NH₃, H₂ or their mixture plasma.

TABLE 1
Dose and LWR/LER data of PEALD EUV UL deposited at different conditions

| | Condition | | | | | | | | | | | | | |
|---|---|---|---|---|---|---|---|---|---|---|---|---|---|---|
| | Ar plasma | | H plasma | | | | | | | O plasma | | | | |
| Sample | A1 | A2 | A3 | A4 | A5 | A6 | A7 | A8 | A9 | A10 | A11 | A12 | A13 | SOG |
| Dose | 70 | 63.5 | 60.5 | 60.5 | 62 | 63.8 | 63.8 | 62.5 | 64 | 63 | 61.5 | 62.2 | 63.4 | 64 |
| (mJ/cm²) | | | | | | | | | | | | | | |
| LWR/LER | 3.1/2.2 | 2.5/1.9 | 2.5/1.9 | 2.5/1.9 | 2.4/1.8 | 2.5/1.8 | 2.5/1.9 | 2.5/1.8 | 2.5/1.8 | 2.7/2.0 | 2.6/2.0 | 2.7/2.0 | 2.8/2.1 | 2.4/1.8 |
| (nm) | | | | | | | | | | | | | | |

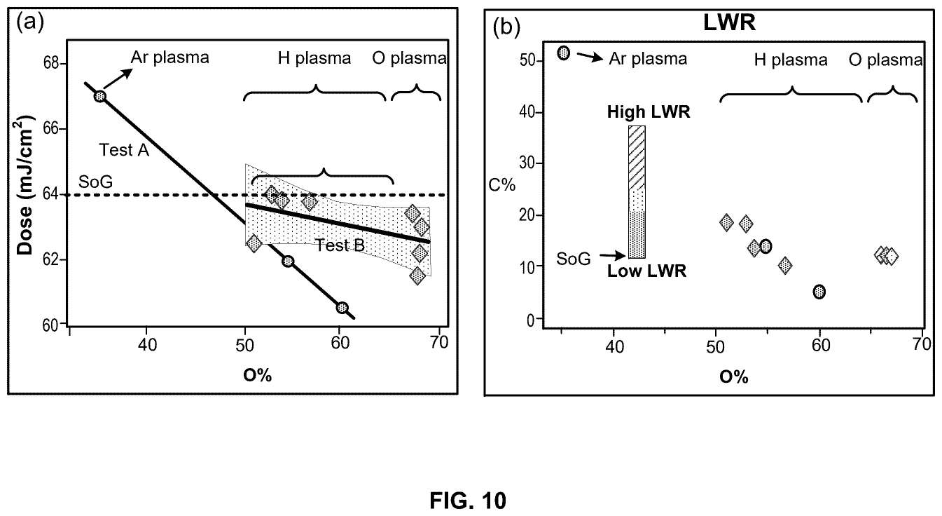

FIGS. 10(a) and (b) illustrates that composition can play a key role for the dose reduction and lithography performance. The dose reduces with an increase in O %, which might be due to the thought that O can generate more secondary electrons than Si and C. Secondary electron can accelerate the reaction in MOR resist. When O %>^{˜}50%, dose is smaller than that of SoG. For improved LWR, there is an optimum composition region, for illustrated examples, the region is O % at 50%-55 at % and C % at 10%-20 at %.

Exemplary photoresist underlayers showed lower dose and comparable lithography performance to SoG can be obtained by tuning the PEALD deposition conditions. the optimize sample is A4, deposited by H plasma. This sample showed ^{˜}5.5% dose reduction. It should be noted that if the MOR changed, the optimum deposition condition might be changed. The composition seems to play an important role, but not the only possible factors; other film properties might also influence the dose and lithography performance of the PEALD photoresist underlayer. One of the advantages of the PEALD EUV photoresist underlayer is that the composition and/or film properties can be easily tuned by varying the deposition parameters. So, for different kinds of MOR, we can easily vary the deposition conditions to tune composition and/or other properties of UL to obtain optimum UL.

FIG. 11 illustrates an exemplary reactor system suitable for use in method 100 or method 700. Reactor system 1100 can be used to perform one or more steps or sub steps as described herein and/or to form one or more structures or portions thereof as described herein.

Reactor system 1100 includes a pair of electrically conductive flat-plate electrodes 4, 2 in parallel and facing each other in the interior 11 (reaction zone) of a reaction chamber 3. A plasma can be excited within reaction chamber 3 by applying, for example, HRF power (e.g., 13.56 MHz or 27 MHz) from power source 25 to one electrode (e.g., electrode 4) and electrically grounding the other electrode (e.g., electrode 2). A temperature regulator can be provided in a lower stage 2 (the lower electrode), and a temperature of a substrate 1 placed thereon can be kept at a desired temperature. Electrode 4 can serve as a gas distribution device, such as a shower plate. Reactant gas, dilution gas, if any, precursor gas, and/or the like can be introduced into reaction chamber 3 using one or more of a gas line 20, a gas line 21, and a gas line 22, respectively, and through the shower plate 4. Although illustrated with three gas lines, reactor system 1100 can include any suitable number of gas lines. Gas line 20 can be coupled to a silicon precursor source 29, gas line 21 can be coupled to an inert gas source 27, and gas line 22 can be coupled to another (e.g., reactant) gas source 28.

In reaction chamber 3, a circular duct 13 with an exhaust line 7 is provided, through which gas in the interior 11 of the reaction chamber 3 can be exhausted. Additionally, a transfer region 5, disposed below the reaction chamber 3, is provided with a seal gas line 24 to introduce seal gas into the interior 11 of the reaction chamber 3 via the interior 16 (transfer zone) of the transfer region 5, wherein a separation plate 14 for separating the reaction zone and the transfer zone is provided (a gate valve through which a wafer is transferred into or from the transfer region 5 is omitted from this figure). The transfer region is also provided with an exhaust line 6. In some embodiments, the deposition and densification steps are performed in the same reaction space, so that two or more (e.g., all) of the (e.g., deposition and adhesion layer) steps can continuously be conducted without exposing the substrate to air or other oxygen-containing atmosphere.

In some embodiments, continuous flow of an inert or carrier gas to reaction chamber 3 can be accomplished using a flow-pass system (FPS), wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber and can carry the precursor gas in pulses by switching between the main line and the detour line, without substantially fluctuating pressure of the reaction chamber.

Reactor system 1100 also includes one or more controller(s) 26 programmed or otherwise configured to cause one or more method steps as described herein to be conducted. Controller(s) 26 are communicated with the various power sources, heating systems, pumps, robotics and gas flow controllers, or valves of the reactor, as will be appreciated by the skilled artisan.

In some embodiments, a dual chamber reactor (two sections or compartments for processing wafers disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

We claim:

1. A method of forming a structure comprising a photoresist underlayer, the method comprising the steps of:
providing a substrate, comprising a carbon layer, within a reaction chamber;
using a first cyclical process, passivating a surface of the carbon layer to form a passivated surface; and
using a second cyclical process, forming a bulk photoresist underlayer overlying the passivated surface,
wherein an oxidant is not provided to the reaction chamber during the first cyclical process.

2. The method of claim 1, wherein the first cyclical process comprises:
providing an inert gas to the reaction chamber;
pulsing a precursor to the reaction chamber; and
pulsing a plasma power to the reaction chamber to form a plasma using the inert gas.

3. The method of claim 2, wherein the inert gas comprises one or more of argon, helium, neon, krypton, xenon, ammonia, hydrazine, or hydrogen.

4. The method of claim 2, further comprising purging the reaction chamber after the step of pulsing the precursor and before pulsing the plasma power.

5. The method of claim 4, wherein a plasma is ignited after the step of purging the reaction chamber.

6. The method of claim 2, wherein the precursor comprises a silicon precursor.

7. The method of claim 6, wherein the silicon precursor comprises oxygen.

8. The method of claim 1, wherein the second cyclical process comprises:
providing a reactant to the reaction chamber;
pulsing a precursor to the reaction chamber; and
pulsing a plasma power to the reaction chamber to form a plasma using the reactant.

9. The method of claim 8, wherein the reactant comprises oxygen.

10. The method of claim 1, wherein the first cyclical process is performed between about 50 cycles and about 80 cycles or between about 60 cycles and about 70 cycles.

11. A method of forming a structure comprising a photoresist underlayer, the method comprising the steps of:
providing a substrate within a reaction chamber;
using a cyclical process, forming a silicon oxycarbide underlayer overlying the substrate; and
forming a metal oxide resist layer overlying the underlayer,
wherein the silicon oxycarbide underlayer comprises about 50 to about 55 atomic percent oxygen.

12. The method of claim 11, wherein the silicon oxycarbide underlayer comprises about 10 to about 20 atomic percent carbon.

13. The method of claim 11, wherein the cyclical process comprises:
providing a reactant to the reaction chamber;
pulsing a precursor to the reaction chamber; and
pulsing a plasma power to the reaction chamber to form a plasma using the reactant.

14. The method of claim 13, wherein the reactant comprises a hydrogen-containing gas.

15. The method of claim 13, wherein the reactant comprises an oxygen-containing gas.

16. The method of claim 13, wherein the precursor comprises a silicon precursor selected from one or more of: 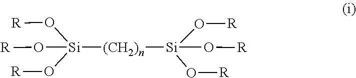
where n is 1 or 2 and each R is independently selected from a C1-C2 alky group; 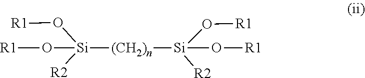
where n is 1 or 2 and each R1 and R2 is independently selected from a C1-C2 alky group or an alkene functional group; 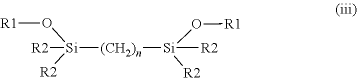
where n is 1 or 2 and each R1 and R2 is independently selected from a C1-C2 alky group or an alkene functional group; or

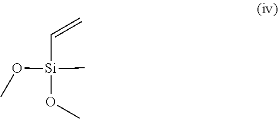

17. The method of claim 13, wherein a chemical formula of the precursor consists of Si, C, H, and O.

18. The method of claim 11, further comprising a step of densifying the silicon oxycarbide underlayer.

19. The method of claim 11, further comprising passivating a surface of the substrate.
